(19) United States
(12) Patent Application Publication
(10) Pub. No.: US 2010/0155646 A1
(43) Pub. Date: Jun. 24, 2010

(54) PIEZOELECTRIC MATERIAL

(75) Inventors: Tatsuo Furuta, Machida-shi (JP); Kaoru Miura, Matsudo-shi (JP); Takanori Matsuda, Chofu-shi (JP); Kenji Takashima, Saitama-shi (JP)

Correspondence Address: FITZPATRICK CELLA HARPER & SCINTO, 1290 Avenue of the Americas, NEW YORK, NY, 10104-3800, US

(73) Assignee: CANON KABUSHIKI KAISHA, Tokyo (JP)

(21) Appl. No.: 12/627,291

(22) Filed: Nov. 30, 2009

(30) Foreign Application Priority Data
Dec. 18, 2008 (JP) 2008-322832

(51) Int. Cl. H01L 41/18

(52) U.S. Cl. 252/62.9 PZ; 252/62.9 R

(57) ABSTRACT

Provided is a piezoelectric material in which the product of the piezoelectric constant and the Young's modulus is large to give excellent piezoelectricity without using lead. A piezoelectric material including a perovskite type crystal represented by a compositional formula of ABO₂N wherein A represents a trivalent cation, and B represents a tetravalent cation provided that A and B are each other than lead, wherein when the number of nitrogen N atoms contained in the piezoelectric material is represented by Nxyz and the number of nitrogen atoms each disposed at a face-centered position in the crystal and in a long axis direction of the crystal, out of the nitrogen atoms the number of which is Nxyz, is represented by Nz, an expression of Nz/Nxyz>1/3 is satisfied. It is preferred that A and B are La and Ti, respectively.

### BACKGROUND OF THE INVENTION

1. Field of the Invention

The present invention relates to a piezoelectric material having piezoelectricity.

2. Description of the Related Art

Usually, piezoelectric materials that have been used in devices contain lead. A typical example of the materials that have been used is PZT (trade name; manufactured by Clevite Co.) which is a solid solution made from PbTiO₃ and PbZrO₃ each having an AMO₃ type perovskite structure. However, in recent years, it has been feared that lead produces a bad effect onto human bodies; thus, in countries, the regulation of the use of lead in glass or high-temperature solder has been started according to RoHS commands or the like. For this reason, also about lead-containing piezoelectric materials used in various devices, lead-free material, in which no lead is contained, has been desired as an alternative material. However, a lead-free material has not yet been found which is large, in particular, in the product of piezoelectricity and Young's modulus, which is a characteristic required for actuator devices.

For example, a unimorph type piezoelectric actuator has a structure in which a piezoelectric material sandwiched, at both ends thereof, by electrodes is bonded to an elastic body. When an electric field is applied to the piezoelectric material from the electrodes at the both ends, stress is generated in accordance with strain generated based on the piezoelectricity, and the Young's modulus of the piezoelectric material. In this way, force for straining end faces of the elastic body is generated, so that the whole of the stacked body can be bent. Accordingly, in order to give a larger flexure to the elastic body, it is desired to use a material about which the product of the piezoelectric constant and the Young's modulus is larger.

A main structure of piezoelectric materials is an ABO₃ type perovskite structure. As illustrated in FIG. 1, however, there is also an ABO₂N type perovskite structure, which is a structure in which one of the three oxygen atoms is substituted with a nitrogen atom. The ABO₃ type perovskite structure is composed of A ions, B ions, and O (oxygen) ions. When the perovskite structure is, for example, a cubic crystal, the cubics thereof each have a structure in which a B ion is arranged at the center of an octahedron made of oxygen atoms and further the oxygen octahedron is surrounded by a hexahedron made of A ions. By a relative displacement between the A ions, the B ion, and the O ions, the crystal structure is changed from the cubic structure to another crystal structure, such as a tetragonal structure, so that ferroelectricity is expressed. The structure of an oxynitride in which the O ions of the ABO₃ type perovskite structure are partially substituted with N (nitrogen) ions is called the ABO₂N type perovskite structure. Incidentally, FIG. 1 illustrates an example of a tetragonal structure in which N ions are arranged in the long axis direction (Z direction) of a lattice, and O ions are arranged in the short axis directions (X and Y directions).

About piezoelectricity, oxides have been mainly investigated so far. Thus, the sum of the valences of the A site and the B site of a perovskite structure is limited to six; however, by making a piezoelectric material into an oxynitride perovskite structure as described above, the piezoelectricity of a combination of new A and B in which the sum of their valences is 7 can be investigated.

Some oxynitrides have been already reported. For example, Japanese Patent Application Laid-Open No. S61-122108 and Japanese Patent No. 3730840 disclose LaTiO₂N and SrTaO₂N as capacitor materials. However, these patent documents neither include any description on piezoelectricity nor any description on any anisotropy of nitrogen; thus, piezoelectricity cannot be expected.

### SUMMARY OF THE INVENTION

The present invention has been accomplished in view of such related art, and an object of the present invention is to provide a piezoelectric material in which the product of the piezoelectric constant and the Young's modulus is large to give excellent piezoelectricity without using lead.

According to a first aspect of the present invention, a piezoelectric material for solving the above-mentioned problems includes a perovskite type crystal represented by a compositional formula of ABO₂N wherein A represents a trivalent cation, and B represents a tetravalent cation provided that A and B are each other than lead, wherein when a number of nitrogen N atoms contained in the piezoelectric material is represented by Nxyz and a number of nitrogen atoms each disposed at a face-centered position of a face crossing a long axis of a crystal, out of the nitrogen atoms the number of which is Nxyz, is represented by Nz, an expression of Nz/Nxyz>1/3 is satisfied.

According to a second aspect of the present invention, a piezoelectric material for solving the above-mentioned problems includes a perovskite type crystal represented by a compositional formula of A′B′O₂N wherein A′ represents a bivalent cation, and B′ represents a pentavalent cation provided that A′ and B′ are each other than lead, wherein when a number of nitrogen N atoms contained in the piezoelectric material is represented by Nxyz and a number of nitrogen atoms each disposed at a face-centered position of a face crossing a long axis of a crystal, out of the nitrogen atoms the number of which is Nxyz, is represented by Nz, an expression of 0≦Nz/Nxyz<0.03, or Nz/Nxyz>1/3 is satisfied.

According to the present invention, it is possible to provide a piezoelectric material wherein the product of the piezoelectric constant and the Young's modulus is large to give excellent piezoelectricity without using lead.

Further features of the present invention will become apparent from the following description of exemplary embodiments with reference to the attached drawings.

### BRIEF DESCRIPTION OF THE DRAWINGS

FIG. 1 is a view for explaining an ABO₂N perovskite structure.

FIG. 2 is a graphical representation for explaining the piezoelectric constant and the Young's modulus in a case where the Nz/Nxyz value of LaTiO₂N is varied (dependency of LaTiO₂N on the nitrogen ratio in the z direction).

FIG. 3 is a graphical representation for explaining the tetragonality, and the product of the piezoelectric constant and the Young's modulus in a case where the Nz/Nxyz value of LaTiO₂N is varied (dependency of LaTiO₂N on the nitrogen ratio in the z direction).

FIG. 4 is a graphical representation for explaining the piezoelectric constant and the Young's modulus in a case where the Nz/Nxyz value of SrNbO₂N is varied (dependency of SrNbO₂N on the nitrogen ratio in the z direction).

FIG. 5 is a graphical representation for explaining the tetragonality, and the product of the piezoelectric constant and the Young's modulus in a case where the Nz/Nxyz value of SrNbO₂N is varied (dependency of SrNbO₂N on the nitrogen ratio in the z direction).

### DESCRIPTION OF THE EMBODIMENTS

Preferred embodiments of the present invention will now be described in detail in accordance with the accompanying drawings.

For the present invention, an investigation has been made about the following combinations of elements in which the sum of the valences of cations in the A site and the B site of a perovskite structure is 7: (1) a trivalent element in the A site, and a tetravalent element in the B site, and (2) a bivalent element in the A site, and a pentavalent element in the B site.

The inventors have conducted extensive studies and found out that in an oxynitride formed of a perovskite type crystal represented by ABO₂N, in accordance with anisotropy of the nitrogen disposition in the oxynitride, the product of the piezoelectricity and the Young's modulus thereof is increased.

The anisotropy of the nitrogen disposition means that when the number of nitrogen atoms contained in a piezoelectric material is represented by Nxyz and the number of nitrogen atoms each disposed at a face-centered position of a face crossing a long axis of the crystal, out of the nitrogen atoms the number of which is Nxyz, is represented by Nz, the value of Nz/Nxyz is a positive value. In the present invention, it is particularly preferred that an expression of Nz/Nxyz>1/3 is satisfied since the product of the piezoelectric constant and the Young's modulus becomes larger. About the upper limit of the value of Nz/Nxyz, the following is satisfied: Nz/Nxyz≦1.

In the present invention, examples of the trivalent cation include La, Bi and Y. Examples of the tetravalent cation include Ti, Zr, Si, Hf, Ge, and Sn. In the combination of A with B, A and B are preferably La and Ti, respectively. When a trivalent element and a tetravalent element are present in the A site and the B site, respectively, it is more preferred that an expression of Nz/Nxyz≧2/3 is satisfied since the product of the piezoelectric constant and the Young's modulus becomes significantly large.

In the perovskite type crystal represented by the compositional formula of A′B′O₂N in the present invention, A′ represents a bivalent cation, examples of which include Sr, Ba and Ca. B′ represents a pentavalent cation, examples of which include Nb, Ta, W, V, and Sb. In the combination of A′ with B′, A′ and B′ are preferably Sr and Nb, respectively.

When a bivalent element and a pentavalent element are present in the A site and the B site, respectively, it is more preferred that an expression of Nz/Nxyz≧4/5 is satisfied since the product of the piezoelectric constant and the Young's modulus becomes significantly large.

When a bivalent element and a pentavalent element are present in the A site and the B site, respectively, it is preferred that at least 97% or more by number of the nitrogen atoms contained in the piezoelectric material are each disposed at the face-centered position of a face crossing the short axis of the crystal since the product of the piezoelectric constant and the Young's modulus becomes significantly large. However, the following should be satisfied: 0≦Nz/Nxyz<0.03.

### EXAMPLES

### Example 1

First, a description is made about Example 1, which is one of the examples and is related to a piezoelectric material in which in a bulk material containing a perovskite type crystal represented by the compositional formula of ABO₂N, A and B are a trivalent cation and a tetravalent cation, respectively, and the nitrogen N atoms are anisotropically disposed.

The present example is based on simulation results of an electronic structure calculation called the first principle calculation. First, an outline of the electronic structure calculation simulation will be described hereinafter.

The first principle calculation is a generic term of electron state calculating methods in which fitting parameters and the like are not used at all, and is a method in which only by inputting the atomic numbers of individual atoms constituting a unit lattice, a molecule or the like and the coordinates of the atoms, an electronic structure calculation can be attained.

As one of the first principle calculation methods, known is a calculation method called the pseudopotential method. This method is a method of preparing the potentials of individual atoms constituting a unit lattice or the like in advance, and then making an electronic structure calculation. The method has an advantage that a calculation for structure optimization can also be made.

The electron state of a system that contains atoms the composition-ratio between which is any value can be relatively simply calculated with a high precision by a method called virtual crystal approximation (VCA). The VCA is a method of preparing, in advance, the potential of virtual atoms in which a plurality of atoms are mixed with each other at a certain compositional ratio, and then performing an electronic structure calculation. Accordingly, when an electronic structure calculation is performed by the pseudopotential method using the VCA, the calculation makes it possible to give calculation results of the electron state of the most stable structure of a system that contains atoms the compositional ratio between which is any value.

A package program for the first principle calculation according to the pseudopotential method using the VCA is a package program called “ABINIT” and developed mainly by Professor X. Gonze of the Cornell University. The piezoelectric constant value described in the present example is a result obtained by performing a calculation using the program “ABINIT”.

According to the compositional formula ABO₂N, the ratio of the oxygen atoms to the nitrogen atoms is 2/1; thus, it is evident that in a unit lattice, the nitrogen disposition has anisotropy. However, about the whole of a thin film or bulk material in which these atoms are gathered, the following two cases are caused: a case where the disposition dependency of the nitrogen atoms is isotropic, and a case where the disposition dependency is anisotropy. Characteristics of the crystal in the individual cases should be different from each other. Thus, the VCA has been used to examine the dependency of the structure on the nitrogen ratio in the Z direction and the dependency of the product of the piezoelectric constant and the Young's modulus thereon.

To the best of the present inventors' researches, there is not any example in which at the time of gaining a relationship of the piezoelectric constant and the Young's modulus relative to the nitrogen ratio in the Z direction, calculations are performed by the method as described above.

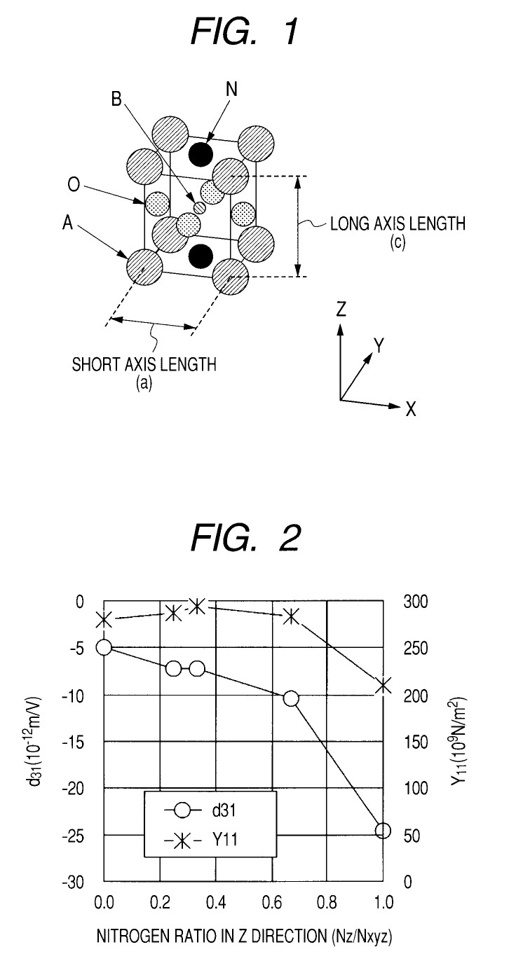

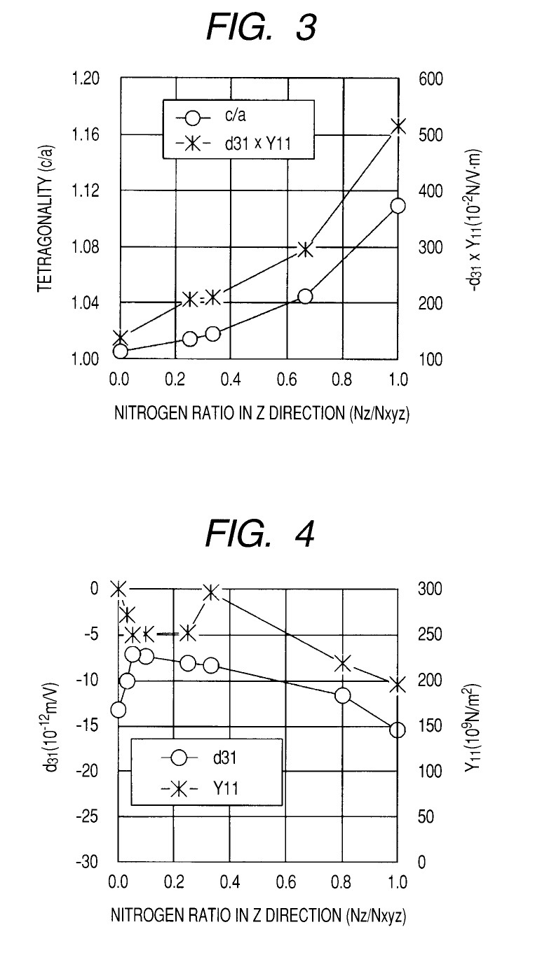

FIGS. 2 and 3 each show results obtained by performing calculations for gaining this relationship, using LaTiO₂N as an example. The Z direction is made consistent with the long axis (major axis) direction of the tetragonal structure. The abscissa in each of the figures represents the nitrogen ratio in the Z direction (long axis direction of the crystal) in FIG. 1, that is, the ratio of Nz/Nxyz in which Nxyz represents the number of nitrogen atoms contained in the material, and Nz represents the number of nitrogen atoms each disposed at a face-centered position of a face crossing a long axis of the crystal, out of the nitrogen atoms the number of which is Nxyz. Accordingly, when the Nz/Nxyz ratio is 1/3, the nitrogen atoms and the oxygen atoms are isotropically disposed; and when the Nz/Nxyz ratio is more than 1/3, the nitrogen atoms are arranged anisotropically in the long axis direction of the crystal.

In FIG. 2, the right ordinate represents the Young's modulus Y₁₁, and the left ordinate represents the piezoelectric constant d₃₁. In FIG. 3, the right ordinate represents a value obtained by multiplying the product of the piezoelectric constant and the Young's modulus by 31 1, and the left ordinate represents the tetragonality, which is the ratio of the long axis length (c) to the short axis length (a), that is, the ratio of c/a.

As is seen from the results, in the state that the nitrogen atoms have anisotropy in the Z direction, the product of the piezoelectric constant and the Young's modulus is larger than in the state that the nitrogen atoms have isotropy in the Z direction. This would result from the following: the tetragonality (c/a) becomes larger, whereby the space for Ti in the B site in the Z direction is widened so that the Ti atoms become easy to move; therefore, the piezoelectric constant is increased.

Generally, it is said that the larger tetragonality, the higher the phase transition temperature. It is therefore suggested that the temperature range in which the crystal is usable for a device may be wide. The piezoelectric constant d₃₁ is a constant representing a strain generated per unit electric field at a constant stress. About a tetragonal structure, d₃₁=d₃₂ are strains in the x and y axis directions with respect to an electric field in the Z axis direction.

The target of the present calculation is not an isotropic material; therefore, the reciprocal number of an S₁₁ component of the compliance matrix (S) is used as the Young's modulus Y₁₁. According to the results in FIG. 3, when the Nz/Nxyz ratio becomes larger than Nz/Nxyz=1/3, in which the oxygen atoms and the nitrogen atoms are isotropically arranged, the product of the piezoelectric constant and the Young's modulus tends to become larger; thus, it is understood that it is more preferred to satisfy an expression of Nz/Nxyz>2/3.

The following will describe a process for producing the present example, to which the present invention is applied. The LaTiO₂N of the present example may be produced irrespective of whether the material is a ceramic product or a thin film.

When the LaTiO₂N is a thin film, the film may be formed by use of a known method such as sputtering, a sol-gel method, laser ablation, or CVD. When the film is formed by means of, for example, a sputtering machine, for example, a metal holder made of La and Ti is prepared in a chamber into which O₂ gas, N₂ gas and Ar gas are caused to flow, and then an Ar beam, which is an ion generating source, is radiated onto the holder. In order to obtain a desired elemental composition and desired structure, a substrate and electrodes to be used, and conditions for forming the film are selected or set. Individual metals sputtered by the Ar beam are allowed to fly onto the substrate set in the chamber, thereby making it possible to form the objective LaTiO₂N piezoelectric film.

When the LaTiO₂N is a ceramic product, for example, at least two are selected as raw materials from lanthanum oxide (La₂O₃), lanthanum nitride (LaN), titanium oxide (TiO₂), and titanium nitride (Ti₃N₄). The raw materials are mixed with each other at a ratio by mole for giving the composition of LaTiO₂N. The mixture is sintered under a pressure within the range of normal pressure to about 10 GPa. In such a way, the LaTiO₂N may be produced.

When the sintering in the present production process is conducted in a closed system, such as a capsule, a composition-deviation of oxygen and nitrogen is easily prevented, this deviation being caused by oxygen or the like from the external. Furthermore, it is desired to handle powder of the raw materials entirely in a glove box. When any redox reaction is reduced as much as possible at the stage of the raw material powder, the composition-deviation can be prevented.

When the sintering is conducted in an ammonia atmosphere, nitrogen is not easily released, either, so that the composition-deviation of oxygen and nitrogen is easily prevented. It is advisable to use, as the method for arranging the nitrogen atoms in the Z direction, a method of sintering the raw materials in an environment for giving anisotropy by press in a monoaxial direction, heating under electric conduction, hot press, or magnetic alignment besides the above-mentioned method.

About methods for measuring the individual elements contained in material, the contents of the metal elements are analyzed by XRF (fluorescent X-ray) measurement, and the contents of the oxygen atoms and the nitrogen atoms are analyzed by combustion gas analysis or XPS (X-ray photoelectron spectroscopy). The anisotropy of the nitrogen atoms can be examined by neutron analysis or the like.

### Example 2

Next, a description is made about Example 2, which is one of the examples and is related to a piezoelectric material in which in a bulk material containing a perovskite type crystal represented by the compositional formula of A′B′O₂N, A′ and B′ are a bivalent cation and a pentavalent cation, respectively, and the nitrogen N atoms are anisotropically arranged.

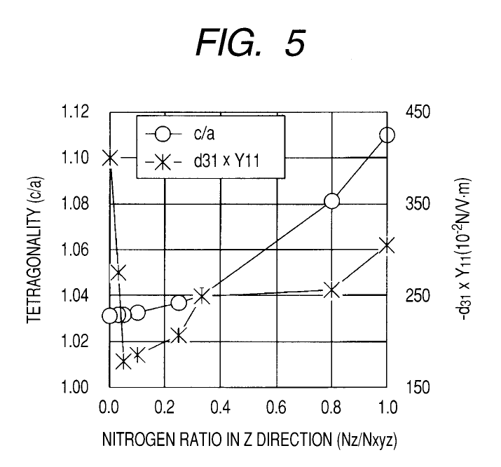

FIGS. 4 and 5 each show results obtained by calculating the dependency of the tetragonality on the nitrogen ratio, and that of the product of the piezoelectric constant and the Young's modulus thereon using SrNbO₂N as an example in the same manner as in Example 1. However, the Z direction in the present example is made consistent with the spontaneous polarization direction of the hexagonal structure of this crystal. The abscissa in each of the figures represents the nitrogen ratio in the Z direction. When the Nz/Nxyz ratio is 1/3, the crystal is in the state that the nitrogen atoms and the oxygen atoms are isotropically arranged. In FIG. 4, the right ordinate represents the Young's modulus Y₁₁, and the left ordinate represents the piezoelectric constant d₃₁. In FIG. 5, the right ordinate represents a value obtained by multiplying the product of the piezoelectric constant and the Young's modulus by −1, and the left ordinate represents the tetragonality, which is the ratio of the long axis length (c) of the crystal lattice to the short axis length (a) thereof, that is, the ratio of c/a.

As is seen from the results, when the Nz/Nxyz ratio is more than 1/3, the product of the piezoelectric constant and the Young's modulus is larger than when the Nz/Nxyz ratio is 1/3. This would result from the following: the tetragonality (c/a) becomes larger, whereby the space for Nb in the B site in the Z direction is widened so that the Nb atoms become easy to move; therefore, the piezoelectric constant is increased.

According to the results in FIG. 5, when the Nz/Nxyz ratio is 0.8 or more, the product of the piezoelectric constant and the Young's modulus tends to be dramatically increased. Thus, it is more preferred that the Nz/Nxyz ratio is 0.8 or more.

It is also seen that when the Nz/Nxyz ratio is 0.03 or less, the product of the piezoelectric constant and the Young's modulus is further increased. This would result primarily from the following: by coulomb force between the B site ions having a high valence of penta-valence and the nitrogen ions arranged in the same XY plane and having a minus tri-valence, binding force is increased so that the Young's modulus is improved. This would result secondarily from the following: the orbit of the B site ions and that of the oxygen ions positioned in the Z direction are hybridized, so that the effective electric charge in the Z direction rises; as a result, the piezoelectricity is also increased since the piezoelectricity is in proportion to the effective charge.

From these results, it is understood that in connection with the anisotropy of nitrogen in the SrNbO₂N, in the state that the Nz/Nxyz ratio is 0.03 or less or larger than 1/3, the product of the piezoelectric constant and the Young's modulus is larger than in the state that the nitrogen atoms are isotropically arranged. In the state that the Nz/Nxyz ratio is larger than 1/3, the tetragonality is also large. Thus, the phase transition temperature is expected to turn large, as described above. It is therefore suggested that the temperature range in which the crystal is usable for a device may be wide.

In the above description, the proportion of the oxygen in the compositional formula ABO₂N and that of the nitrogen therein have been thoroughly represented by 2 and 1, respectively. However, the composition is not limited thereto. Even when the composition is deviated by defects or the like, the same advantages are obtained.

However, when oxygen defects are increased, the electric field resistance of the material is increased so that no piezoelectricity is expressed in a low electric field. It is therefore desired that the sum of the proportions of the oxygen and the nitrogen is 2.8 or more in the present example since the material is easily subjected to polarizing treatment.

The present invention may be applied to a device using a piezoelectric element, which is a piezoelectric material having electrodes, such as an ultrasonic motor, a vibration sensor, an inkjet head, a transformer, or a filter. The invention may also be applied to a device using ferroelectricity, such as a ferroelectric memory.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2008-322832, filed Dec. 18, 2008, which is hereby incorporated by reference herein in its entirety.

What is claimed is:

1. A piezoelectric material, comprising a perovskite type crystal represented by a compositional formula of ABO₂N in which A represents a trivalent cation, and B represents a tetravalent cation provided that A and B are each other than lead,
wherein when the number of nitrogen N atoms contained in the piezoelectric material is represented by Nxyz and the number of nitrogen atoms each disposed at a face-centered position of a face crossing a long axis of the crystal, out of the nitrogen atoms the number of which is Nxyz, is represented by Nz, an expression of Nz/Nxyz>1/3 is satisfied.

2. The piezoelectric material according to claim 1, wherein A is La, and B is Ti.

3. A piezoelectric material, comprising a perovskite type crystal represented by a compositional formula of A′B′ O₂N wherein A′ represents a bivalent cation, and B′ represents a pentavalent cation provided that A′ and B′ are each other than lead,
wherein when the number of nitrogen N atoms contained in the piezoelectric material is represented by Nxyz and the number of nitrogen atoms each disposed at a face-centered position of a face crossing a long axis of the crystal, out of the nitrogen atoms the number of which is Nxyz, is represented by Nz, an expression of 0≦Nz/Nxyz<0.03, or Nz/Nxyz>1/3 is satisfied.

4. The piezoelectric material according to claim 3, wherein A′ is Sr, and B′ is Nb.

5. The piezoelectric material according to claim 3, wherein at least 97% or more by number of the nitrogen atoms contained in the piezoelectric material are each disposed at the face-centered position in the crystal and in the short axis direction of the crystal.

6. The piezoelectric material according to claim 3, wherein when the number of the nitrogen atoms contained in the piezoelectric material is represented by Nxyz and the number of nitrogen atoms each disposed at the face-centered position in the crystal and in the long axis direction of the crystal, out of the nitrogen atoms the number of which is Nxyz, is represented by Nz, an expression of Nz/Nxyz≧2/3 is satisfied.

7. The piezoelectric material according to claim 3, wherein when the number of the nitrogen N atoms contained in the piezoelectric material is represented by Nxyz and the number of nitrogen atoms each disposed at the face-centered position in the crystal and in the long axis direction of the crystal, out of the nitrogen atoms the number of which is Nxyz, is represented by Nz, an expression of Nz/Nxyz≧4/5 is satisfied.
